(19) United States
(12) Patent Application Publication
(10) Pub. No.: US 2026/0293722 A1
(43) Pub. Date: Sep. 24, 2026

(54) SEMICONDUCTOR DEVICE

(71) Applicants: KABUSHIKI KAISHA TOSHIBA, Kawasaki-shi (JP); TOSHIBA ELECTRONIC DEVICES & STORAGE CORPORATION, Kawasaki-shi (JP)

(72) Inventor: Eitaro MIYAKE, Tachikawa Tokyo (JP)

(73) Assignees: KABUSHIKI KAISHA TOSHIBA, Kawasaki-shi (JP); TOSHIBA ELECTRONIC DEVICES & STORAGE CORPORATION, Kawasaki-shi (JP)

(21) Appl. No.: 19/369,465

(22) Filed: Oct. 27, 2025

(30) Foreign Application Priority Data
Mar. 18, 2025 (JP) 2025-043654

(51) Int. Cl. H01L 23/538; H01L 23/00; H01L 23/31; H01L 25/065

(52) U.S. Cl. CPC H10W 70/65; H10W 70/611; H10W 74/114; H10W 90/00; H10W 90/736

(57) ABSTRACT

A semiconductor device according to the embodiment includes at least one semiconductor chip, a metal plate, a substrate, and a resin body. The plate is electrically connected to the semiconductor chip at a first surface facing the semiconductor chip in a first direction. The substrate is disposed on the side of the semiconductor chip opposite to the plate in the first direction. The substrate includes a first conductive portion, a second conductive portion, a third conductive portion, and a transmission part. The first conductive portion and the second conductive portion are electrically connected to the semiconductor chip. The third conductive portion receives a control current. The transmission part is electrically connected to the first conductive portion, the second conductive portion, and the third conductive portion, and is capable of transmitting the control current in an insulated state.

### CROSS-REFERENCE TO RELATED APPLICATION

This application is based upon and claims the benefit of priority from Japanese Patent Application No. 2025-043654, filed on Mar. 18, 2025; the entire contents of which are incorporated herein by reference.

### FIELD

Embodiments described herein relate generally to a semiconductor device.

### BACKGROUND

There is a semiconductor device in which a semiconductor relay is used as a means for transmitting ON/OFF of a current, and a semiconductor chip such as a metal oxide semiconductor field effect transistor (hereinafter, referred to as MOSFET) is used as an output switching element in the semiconductor relay.

In the above-described semiconductor device, in order to improve heat dissipation characteristics of the semiconductor relay capable of handling a large current, it is necessary to increase a thermal conductivity of a member in contact with the semiconductor chip which is a heat source. For example, it is conceivable to mount a semiconductor chip on a printed wiring board, but a resin portion constituting the board does not dissipate heat sufficiently.

Furthermore, when a copper frame is used, for manufacturing purposes, it is necessary to expose hanging pins for holding a wiring and electrodes, which form a part of the copper frame located inside a package, from the package. Since the hanging pin has an electric potential, it is necessary to ensure a creepage distance from an adjacent electrode in terms of design, it is necessary to ensure insulation in terms of use, and thus an increase in size becomes an issue.

### BRIEF DESCRIPTION OF THE DRAWINGS

FIG. 1 is a plan view showing an example of a structure of a semiconductor device according to a first embodiment.

FIG. 2 is a cross-sectional view taken along line II-II in FIG. 1.

FIG. 3 is a plan view of the semiconductor device excluding members on the +Z side with respect to a substrate.

FIG. 4 is a circuit diagram showing a circuit configuration of the semiconductor device according to the first embodiment.

FIG. 5 is a plan view showing an example of a structure of a semiconductor device according to a second embodiment.

FIG. 6 is a cross-sectional view taken along line II-II in FIG. 5.

### DETAILED DESCRIPTION

A semiconductor device according to an embodiment includes at least one semiconductor chip, a plate formed of a metal, a substrate, and a resin body. A metal plate is electrically connected to the semiconductor chip at a first surface that faces the semiconductor chip in a first direction. The substrate is disposed on the side of the semiconductor chip opposite to the plate in the first direction. The resin body covers the semiconductor chip, the first surface of the plate, and the substrate. At least a second surface of the plate on the side opposite to the first surface in the first direction is exposed to the outside of the resin body. The substrate has a first conductive portion, a second conductive portion, a third conductive portion, and a transmission part. The first conductive portion and the second conductive portion are electrically connected to the semiconductor chip. The third conductive portion receives a control current. The transmission part is electrically connected to the first conductive portion, the second conductive portion, and the third conductive portion, and is capable of transmitting the control current in an insulated state.

Hereinafter, a semiconductor device according to an embodiment will be described with reference to the drawings. In the following description, components having the same or similar functions are denoted by the same reference numerals. In addition, duplicate descriptions thereof may be omitted.

In addition, in each of the following embodiments, when components (for example, circuits, wiring, various voltages and signals, and the like) that are given reference symbols with distinguishing numbers/letters at the end do not need to be distinguished from each other, descriptions (reference symbols) with the numbers/letters at the end omitted may be used.

### First Embodiment

The configuration of the first embodiment of the semiconductor device will be described below.

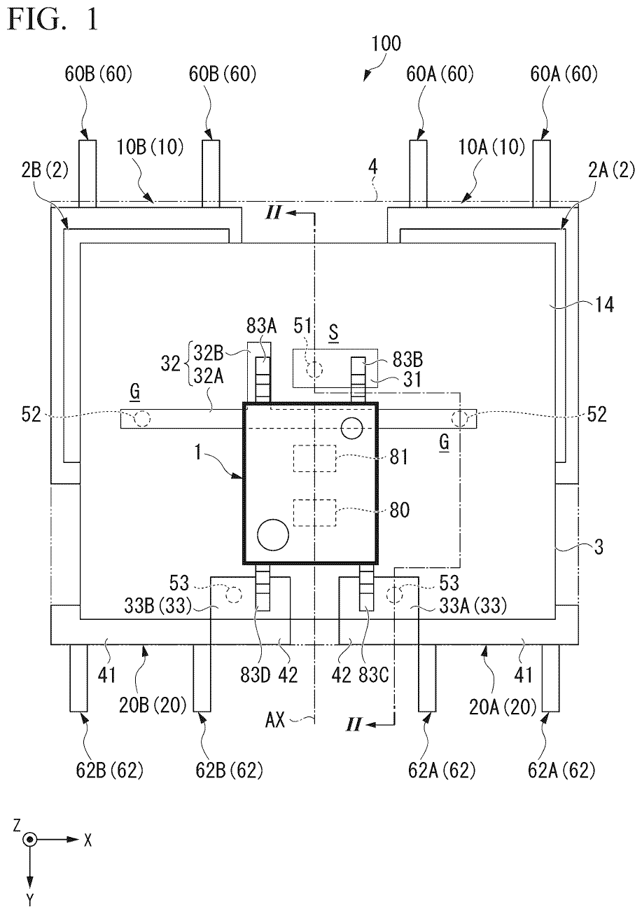

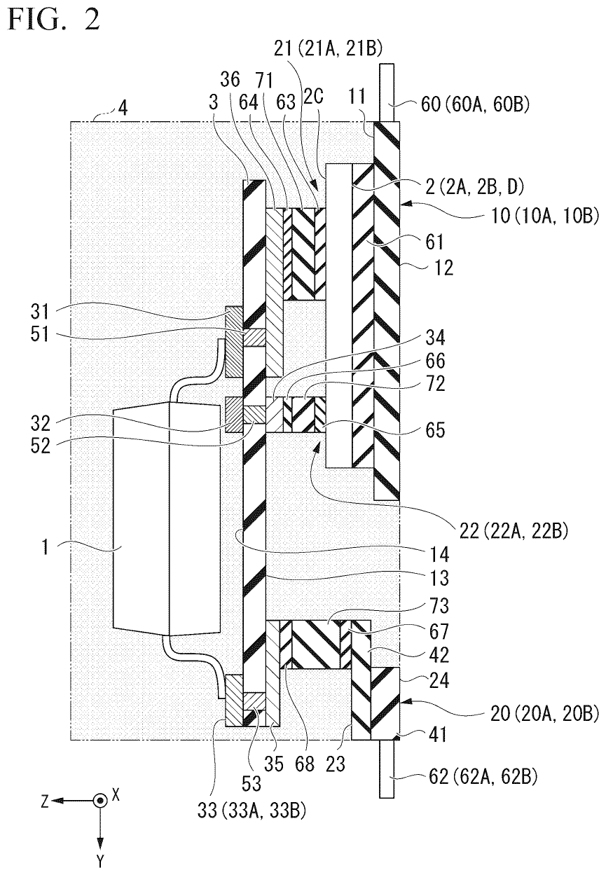

FIG. 1 is a schematic plan view illustrating a structure of a semiconductor device 100 of the embodiment. FIG. 2 is a cross-sectional view taken along line II-II in FIG. 1. As shown in FIGS. 1 and 2, the semiconductor device 100 includes a transmission part 1, semiconductor chips 2 (2A and 2B), a substrate 3, a resin body 4, first frames (plates) 10 (10A and 10B), and second frames (second plates) 20 (20A and 20B).

The semiconductor chip 2 has a rectangular shape in plan view, and at least one semiconductor chip 2 is provided. In the example shown in FIG. 1, two semiconductor chips 2A and 2B are provided. The two semiconductor chips 2A and 2B are disposed apart from each other in a left-right direction of FIG. 1. Each of the two semiconductor chips 2A and 2B is a semiconductor element. For example, each of the two semiconductor chips 2A and 2B is a field effect transistor. As a more specific example, the two semiconductor chips 2A and 2B are MOSFETs (for example, power MOSFETs). The semiconductor chips 2A and 2B are used to control a current in a photorelay which will be described below. The current controlled by the photorelay may be either DC or AC.

The semiconductor chip 2 has a first electrode 21 and a second electrode 22. The first electrode 21 and the second electrode 22 are disposed on a facing surface 2C that faces the substrate 3 in a first direction (the left-right direction in FIG. 2) in which the semiconductor chip 2 and the substrate 3 face each other. The first electrode 21 is, for example, a source electrode of the semiconductor chip 2. The second electrode 22 is, for example, a gate electrode of the semiconductor chip 2.

In an XYZ coordinate system shown in each of the drawings, a Z direction is an up-down direction which is parallel to a direction (the left-right direction in FIG. 2) in which the semiconductor chip 2 and the substrate 3 are arranged in the cross section taken along line II-II. The Z direction corresponds to the first direction. In the Z direction, the side on which the substrate 3 is disposed is defined as the positive side (the +Z side), and the side on which the semiconductor chip 2 is disposed is defined as the negative side (the −Z side). The positive side in the Z direction may be referred to as the “upper side,” and the negative side in the Z direction may be referred to as the “lower side.” In addition, in plan view, the direction (the left-right direction in FIG. 1) that is parallel to the direction in which the two semiconductor chips 2A and 2B are arranged is referred to as an X direction. The X direction corresponds to a third direction. A direction (the up-down direction in FIG. 1) perpendicular to both the X direction and the Z direction and in which the first frames 10 (10A and 10B) and the second frames 20 (20A and 20B) described below are arranged in plan view is referred to as a Y direction. The Y direction corresponds to a second direction. The terms “up-down direction,” “upper side” and “lower side” are merely names used for the purpose of explanation and do not limit the actual positional relationship and direction.

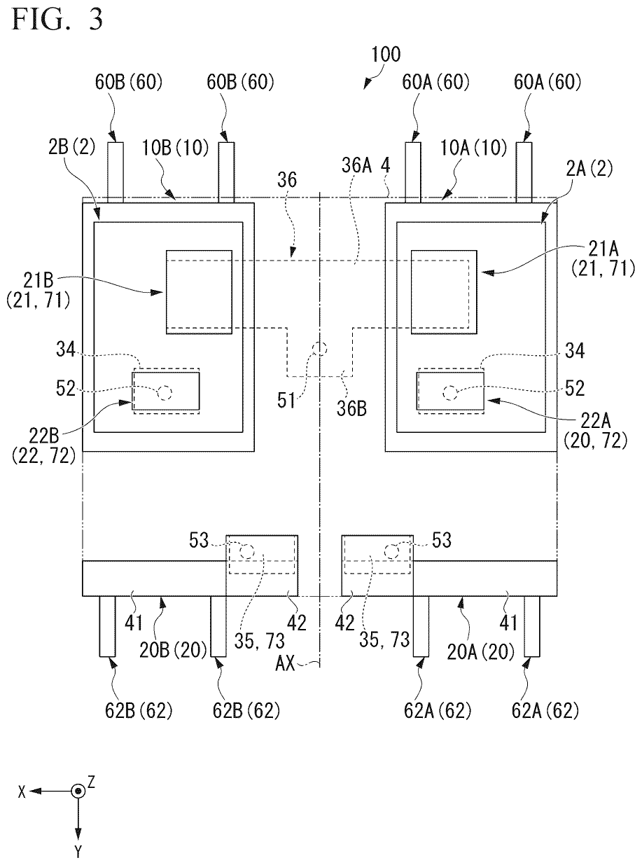

FIG. 3 is a plan view of the semiconductor device 100 excluding members on the +Z side of the substrate 3. However, conductors located on a third surface 13, which is located on the −Z side of the substrate 3 and faces the semiconductor chips 2A and 2B, are shown by dashed lines.

As shown in FIGS. 1 to 3, the first frames 10 (10A and 10B) are plates having a rectangular shape in plan view and are made of a metal. The first frames 10A and 10B overlap the semiconductor chips 2A and 2B in plan view. The first frames 10A and 10B have dimensions larger than the semiconductor chips 2A and 2B in both the X direction and the Y direction in plan view. The first frames 10A and 10B have hanging pins 60 (60A and 60B), respectively. Each of the hanging pins 60A and 60B has an axial shape which extends from a side surface located on the −Y side of each of the first frames 10A and 10B to the −Y side. The hanging pins 60A and 60B are portions of the semiconductor device 100 that are supported by a die when the resin body 4 is molded using the die, for example. The hanging pins are cut and removed in a process following resin sealing and are roughly flush with a side surface of the molded resin body 4, but remaining portions thereof are not insulated and are exposed.

The first frames 10A and 10B are formed of, for example, copper (Cu) or a copper alloy. The first frames 10A and 10B are disposed to be spaced apart from each other in the X direction. The first frames 10A and 10B are electrically connected to the semiconductor chips 2A and 2B on the first surface 11 side on which they face each other in the Z direction. A drain D of the semiconductor chip 2 is electrically connected to the first frame 10. The first frames 10A and 10B are electrically connected to the semiconductor chips 2A and 2B via a conductive member 61 made of a metal such as a silver-based bonding material such as silver paste or sintered silver, or solder. Therefore, the −Z side of the semiconductor chips 2A and 2B is entirely in contact with the metal. Second surfaces 12 of the first frames 10A and 10B that face the −Z side on the side opposite to the first surfaces 11 in the Z direction are exposed to the outside of the resin body 4.

The second frames 20 (20A and 20B) are L-shaped plates in plan view and are made of a metal. As an example, the second frames 20A and 20B are made of copper (Cu) or a copper alloy. The second frames 20 (20A and 20B) are disposed to be spaced apart from the first frames 10 (10A and 10B) in the Y direction. The second frames 20 (20A and 20B) are disposed apart from the first frames 10 (10A and 10B) to the +Y side. As shown in FIG. 2, fifth surfaces 24 of the second frames 20 (20A and 20B) that face the −Z side on the side opposite to a facing surface 23 facing the substrate 3 in the Z direction are exposed to the outside of the resin body 4. The second frames 20A and 20B exposed to the outside constitute external connection terminals to which a control current of a photorelay which will be described below is input. The second frames 20A and 20B are disposed to be spaced apart from each other in the X direction. The second frames 20A and 20B are formed in line symmetry with respect to a line AX that passes through a center of an X-Y plane of the transmission part 1.

Each of the second frames 20A and 20B has a first portion 41 and a second portion 42. The first portion 41 has the fifth surface 24. The first portion 41 faces the first frame 10 in the Y direction. The first portion 41 extends in the X direction with a constant creepage distance from the first frame 10. The second portion 42 is disposed at a portion of an end portion of the first portion 41 on the line AX side in the X direction, as shown in FIG. 3. As shown in FIG. 2, the second portion 42 is provided on the substrate 3 side (the +Z side) of the first portion 41 in the Z direction. The second portion 42 is located on the +Z side with respect to the first frame 10 and does not face the first frame 10 in the Y direction. The second portion 42 protrudes toward the first frame 10 on the −Y side with respect to the first portion 41 in the Y direction. The second portion 42 that protrudes toward the −Y side with respect to the first portion 41 is not exposed to the outside of the resin body 4.

Therefore, the creepage distance between the first frame 10 and the second frame 20 is determined by the distance in the Y direction between the first frame 10 and the first portion 41, regardless of a position of the second portion 42. In other words, since the creepage distance between the first frame 10 and the second frame 20 is determined by the first portion 41, which has a long distance from the first frame 10, rather than the second portion 42, which has a short distance from the first frame 10, a sufficient creepage distance can be secured.

The second frames 20A and 20B have hanging pins 62 (62A and 62B), respectively. Each of the hanging pins 62A and 62B has an axial shape which extends from a side surface located on the +Y side of each of the second frames 20A and 20B to the +Y side. The hanging pins 62A and 62B are portions of the semiconductor device 100 that are supported by a die when the resin body 4 is molded using the die, for example.

The substrate 3 is disposed to be spaced apart from the semiconductor chip 2 in the Z direction to the +Z side opposite to the first frame 10 and the second frame 20. The substrate 3 is made of, for example, a resin. The substrate 3 is, for example, a printed wiring board. The substrate 3 is made of, for example, a glass epoxy resin. The substrate 3 has a rectangular shape in plan view as shown in FIG. 1. An exterior of the substrate 3 on the −Y side is located on the +Y side with respect to an exterior of the semiconductor chip 2 on the −Y side. The exterior of substrate 3 on the +Y side is located on the −Y side with respect to the exterior of second frame 20 on the +Y side. An exterior of substrate 3 in the X-direction is located on the line AX side with respect to an exterior of semiconductor chip 2 in the X-direction.

The substrate 3 has the third surface 13 located on the −Z side and facing the semiconductor chip 2, and a fourth surface 14 located on the +Z side opposite to the third surface 13. The third surface 13 is provided with a fourth conductive portion 34, a fifth conductive portion 35, and a connection wiring 36. The fourth surface 14 is provided with a first conductive portion 31, a second conductive portion 32, and a third conductive portion 33.

The connection wiring 36 has a third portion 36A that extends in the X direction and a fourth portion 36B that extends from a center of the third portion 36A in the X direction to the +Y side. Both ends of the third portion 36A in the X direction face the first electrode 21 in the Z direction and are electrically connected to the first electrode 21. That is, the third portion 36A of the connection wiring 36 electrically connects the first electrodes 21 of the two semiconductor chips 2A and 2B. As shown in FIG. 2, the fourth portion 36B of the connection wiring 36 is connected to the first conductive portion 31 through a via 51.

The semiconductor device 100 has a first conductor 71 disposed between the connection wiring 36 and the first electrode 21. The first conductor 71 is made of a conductive material (for example, copper). The first conductor 71 is electrically connected to the first electrode 21 via a conductive member 63 such as a silver-based bonding material such as silver paste or sintered silver, or solder, and is connected to the connection wiring 36 via a conductive member 64. Therefore, the first conductive portion 31 is electrically connected to the first electrodes 21 (the source electrodes) of the two semiconductor chips 2A and 2B through the via 51, the connection wirings 36 and the first conductor 71.

The first conductor 71 adjusts the distance between the connection wiring 36 and the first electrode 21. By adjusting the distance between the connection wiring 36 and the first electrode 21 using the first conductor 71 to separate them in the Z direction, it is possible to curb the substrate 3 coming into contact with the semiconductor chip 2 and ensure pressure resistance of the semiconductor chip 2.

The fourth conductive portion 34 is disposed at a position on each of the semiconductor chips 2A and 2B that faces the second electrode 22 in the Z direction, and is electrically connected to the second electrode 22. The fourth conductive portion 34 is electrically connected to the second conductive portion 32 through a via 52. The second conductive portion 32 has a fifth portion 32A that extends in the X direction across the line AX, and a sixth portion 32B that extends from the fifth portion 32A to the −Y side at a position on the −X side with respect to the first conductive portion 31. Both ends of the fifth portion 32A in the X direction are connected to the vias 52, respectively.

The semiconductor device 100 has a second conductor 72 disposed between the fourth conductive portion 34 and the second electrode 22. The second conductor 72 is made of a conductive material (for example, copper). The second conductor 72 is electrically connected to the second electrode 22 via a conductive member 65 such as a silver-based bonding material such as silver paste or sintered silver, or solder, and is connected to the fourth conductive portion 34 via a conductive member 66. Therefore, the sixth portion 32B of the second conductive portion 32 is electrically connected to the second electrodes 22 (the gate electrodes) of the two semiconductor chips 2A and 2B via the two vias 52, the fourth conductive portion 34 and the second conductor 72, respectively.

The second conductor 72 adjusts the distance between the fourth conductive portion 34 and the second electrode 22. By adjusting the distance between the fourth conductive portion 34 and the second electrode 22 using the second conductor 72 to separate them in the Z direction, it is possible to curb the substrate 3 coming into contact with the semiconductor chip 2 and ensure the pressure resistance of the semiconductor chip 2. Moreover, parallelism between the semiconductor chips 2A and 2B and the substrate 3 can be easily adjusted.

The fifth conductive portion 35 is disposed at a position at which it faces the second portion 42 of each of the second frames 20A and 20B in the Z direction and is electrically connected to the second portions 42. The fifth conductive portion 35 is electrically connected to the third conductive portion 33 through a via 53. The third conductive portion 33 receives the control current.

The semiconductor device 100 has a third conductor 73 disposed between the fifth conductive portion 35 and the second portion 42 of each of the second frames 20A and 20B. The third conductor 73 is made of a conductive material (for example, copper). The third conductor 73 is electrically connected to the second portion 42 of each of the second frame 20A and 20B via a conductive member 67 such as a silver-based bonding material such as silver paste or sintered silver, or solder, and is connected to the fifth conductive portion 35 via a conductive member 68. Therefore, the third conductive portion 33 is electrically connected to the second portion 42 of each of the second frames 20A and 20B through the via 53, the fifth conductive portion 35 and the third conductor 73.

Since the second frame 20 has the second portion 42 that is located on the +Z side with respect to the first frame 10 and does not face the first frame 10 in the Y direction, and the second portion 42 is provided to protrude to the −Y side with respect to the first portion 41, while a sufficient creepage distance between the first frame 10 and the second frame 20 is ensured, it is possible to move a connection position between the fifth conductive portion 35 and the second frame 20 due to the third conductor 73 closer to the first frame 10, which contributes to miniaturizing the substrate 3.

The third conductor 73 adjusts the distance between the fifth conductive portion 35 and the second portion 42 of each of the second frames 20A and 20B. By adjusting the distance between the fifth conductive portion 35 and the second portion 42 of each of the second frames 20A and 20B using the third conductor 73, the parallelism between the second frames 20A and 20B and the substrate 3 can be easily adjusted.

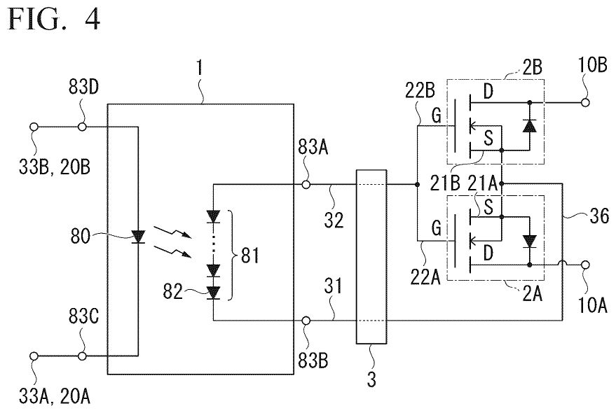

The semiconductor device 100 of the embodiment is, for example, a photorelay. In this case, the transmission part 1 includes a photocoupler (an optical coupling device). The photocoupler includes an optically coupled insulating circuit. The transmission part 1 is electrically connected to the semiconductor chips 2A and 2B via the first conductive portion 31, the second conductive portion 32, the fourth conductive portion 34 and the connection wiring 36. As shown in FIGS. 1 and 4, the transmission part 1 includes, as components of the optically coupled insulating circuit, a light emitting element 80 and a light receiving element 81. The light emitting element 80 is, for example, a light emitting diode (LED).

The transmission part 1 has a connection terminal 83A, a connection terminal 83B, a connection terminal 83C, and a connection terminal 83D. One node (for example, a cathode) of the light emitting element 80 is connected to the connection terminal 83C. The other node (for example, an anode) of the light emitting element 80 is connected to the connection terminal 83D. The connection terminals 83C and 83D are input terminals of the transmission part 1. A control current for controlling the photorelay by the transmission part 1 is applied to the connection terminals 83C and 83D via the second frames 20A and 20B and the third conductive portions 33A and 33B which are external connection terminals.

The light receiving element 81 is, for example, a photodiode array. The light receiving element 81 includes, for example, several to several tens of photodiodes 82 connected in series. The light receiving element 81 may be a phototransistor. One node (for example, a cathode) of the light receiving element 81 is connected to the connection terminal 83B. The other node (for example, an anode) of the light receiving element 81 is connected to the connection terminal 83A. The connection terminals 83A and 83B are output terminals of a photocoupler.

The second electrodes (the gate electrodes) 22A and 22B of the semiconductor chips 2A and 2B are commonly connected to the connection terminal (the anode) 83A of the light receiving element 81 via the fourth conductive portion 34 and the second conductive portion 32. The first electrodes (the source electrodes) 21A and 21B of the semiconductor chips 2A and 2B are commonly connected to the connection terminal (the cathode) 83B of the light receiving element 81 via the connection wiring 36 and the first conductive portion 31. The drain D of the semiconductor chip 2A is connected to the first frame 10A which is an external connection terminal. The drain D of the semiconductor chip 2B is connected to the first frame 10B which is an external connection terminal.

The second frames 20A and 20B which are external connection terminals serve as input terminals of the photorelay in the semiconductor device 100 of the embodiment. The first frames 10A and 10B which are external connection terminals serve as output terminals of the photorelay in the semiconductor device 100 of the embodiment.

In the transmission part 1 as a photocoupler, the light emitting element 80 outputs light in accordance with a voltage applied to the second frames 20A and 20B. That is, the light emitting element 80 converts an electrical signal into an optical signal.

The light receiving element 81 receives the optical signal from the light emitting element 80. The light receiving element 81 generates a voltage of, for example, 7 V to several tens of volts in accordance with the received optical signal. That is, the light receiving element 81 converts the optical signal into an electrical signal. The light receiving element 81 supplies the generated voltage as a gate voltage of the semiconductor chip 2 to the semiconductor chip 2 via the second conductive portion 32 and the fourth conductive portion 34.

Each of the semiconductor chips 2A and 2B is driven in response to a voltage generated by the light receiving element 81. The semiconductor chips 2A and 2B output a current in accordance with a voltage applied to the gate. Therefore, when the semiconductor chips 2A and 2B are in an ON state, the photorelay passes the current.

In the transmission part 1, when the light emitting element 80 is in an OFF state, an output of the voltage from the light receiving element 81 is stopped. Thus, the semiconductor chips 2A and 2B are in the OFF state. As a result, the first frames 10A and 10B which serve as the output terminals of the photorelay are brought into an electrically non-conductive state. Therefore, when the semiconductor chips 2A and 2B are in the OFF state, the photorelay cuts off the current. In this manner, the semiconductor device 100 of the present embodiment is operated as a photorelay.

The resin body 4 covers the semiconductor chip 2, the first surface 11 of the first frame 10, and the substrate 3. In FIGS. 1 to 3, the resin body 4 is indicated by a two-dot chain line to ensure visibility. As shown in FIG. 2, the resin body 4 is provided up to a position on the +Z side with respect to the transmission part 1 on the +Z side. The resin body 4 is provided on the −Z side up to a position at which it is flush with the second surface 12 of the first frame 10 and the fifth surface 24 of the second frame 20 in a state in which the second surface 12 and the fifth surface 24 are exposed.

As shown in FIGS. 1 to 3, the resin body 4 is provided on the −Y side up to a position at which it is flush with side surfaces of the first frames 10A and 10B on the-Y side in a state in which the side surfaces are exposed. The resin body 4 is provided on the +Y side up to a position at which it is flush with side surfaces of the second frames 20A and 20B on the +Y in a state in which the side surfaces are exposed. The resin body 4 is provided on both sides in the X direction up to a position at which it is flush with outer side surfaces of the first frames 10A and 10B and the second frames 20A and 20B in a state in which the outer side surfaces are exposed.

The first frames 10A and 10B have the second surface 12, the side surface on the −Y side, and both the outer side surfaces in the X direction that are not covered with the resin body 4 and are exposed to the outside, such that heat generated by the semiconductor chip 2 in the ON state is transferred to the first frame 10 via the conductive member 61 and can be effectively dissipated from the exposed surfaces. The resin body 4 may be made of, for example, an epoxy resin, a polyimide resin, or other resins.

Although the first frames 10A and 10B have the hanging pins 60A and 60B, and the second frames 20A and 20B have the hanging pins 62A and 62B, since the first frames 10A and 10B and the second frames 20A and 20B are external connection terminals, they are intended to be exposed to the outside. Therefore, the remaining hanging pins 60A and 60B and hanging pins 62A and 62B that have been cut off can ensure the creepage distances from other components. Furthermore, the end surfaces of the hanging pins 60A and 60B and the hanging pins 62A and 62B that are cut off during assembly are exposed flush with the side surfaces of the resin body 4.

In a method for manufacturing the semiconductor device 100 having the above-described configuration, first, the semiconductor chip 2 is mounted on the first surfaces 11 of the first frame 10A and 10B via the conductive member 61, the first conductor 71 is connected to the first electrode 21 of the semiconductor chip 2 via the conductive member 63, and the second conductor 72 is connected to the second electrode 22 via the conductive member 65. Further, the third conductor 73 is connected to the facing surfaces 23 of the second frames 20A and 20B via the conductive member 67.

On the other hand, in the substrate 3, the first conductive portion 31, the second conductive portion 32, and the third conductive portion 33 are formed on the fourth surface 14 to mount the transmission part 1, and the fourth conductive portion 34, the fifth conductive portion 35, and the connection wiring 36 are formed on the third surface 13 by connecting them to the vias 51, 52, and 53.

Thereafter, in a state in which each of the hanging pins 60A and 60B and the hanging pins 62A and 62B is supported to position the first frames 10A and 10B and the second frames 20A and 20B, the first conductor 71, the second conductor 72 and the third conductor 73 are connected to the connection wiring 36, the fourth conductive portion 34 and the fifth conductive portion 35 of the substrate 3 via the conductive member 63, the conductive member 66 and the conductive member 68, respectively. Thus, the first frames 10A and 10B, the second frames 20A and 20B, the semiconductor chip 2, and the substrate 3 are integrated together. Then, in a state in which each of the hanging pins 60A and 60B and the hanging pins 62A and 62B is supported by a mold, and the second surfaces 12 of the first frames 10A and 10B and the fifth surfaces 24 of the second frames 20A and 20B are in contact with the mold, the resin body 4 is molded by injection molding. Thus, the semiconductor device 100 is obtained.

According to at least one embodiment described above, since the first conductive portion and the second conductive portion electrically connected to the semiconductor chips 2A and 2B, the third conductive portion to which a control current is input, and the transmission part are provided on the substrate 3 disposed on the +Z side of the semiconductor chips 2A and 2B, and the semiconductor chips 2A and 2B are electrically connected to the first frames 10A and 10B disposed on the −Z side of the semiconductor chips 2A and 2B, and the first frames 10A and 10B are exposed to the outside of the resin body 4 on the second surfaces 12, even in a configuration in which the resin body 4 is provided, heat generated in the semiconductor chip 2 in the ON state can be effectively dissipated via the first frames 10A and 10B which are in full contact with the semiconductor chips, and a large current can be handled.

According to at least one embodiment, the hanging pins 60A and 60B and the hanging pins 62A and 62B are provided on the first frames 10A and 10B and the second frames 20A and 20B which are external connection terminals, respectively.

### Second Embodiment

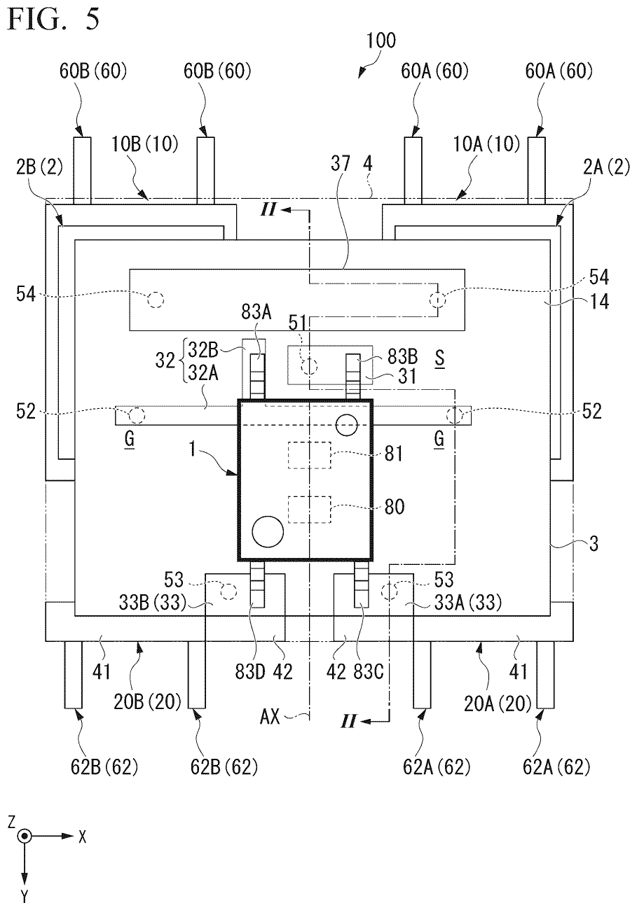

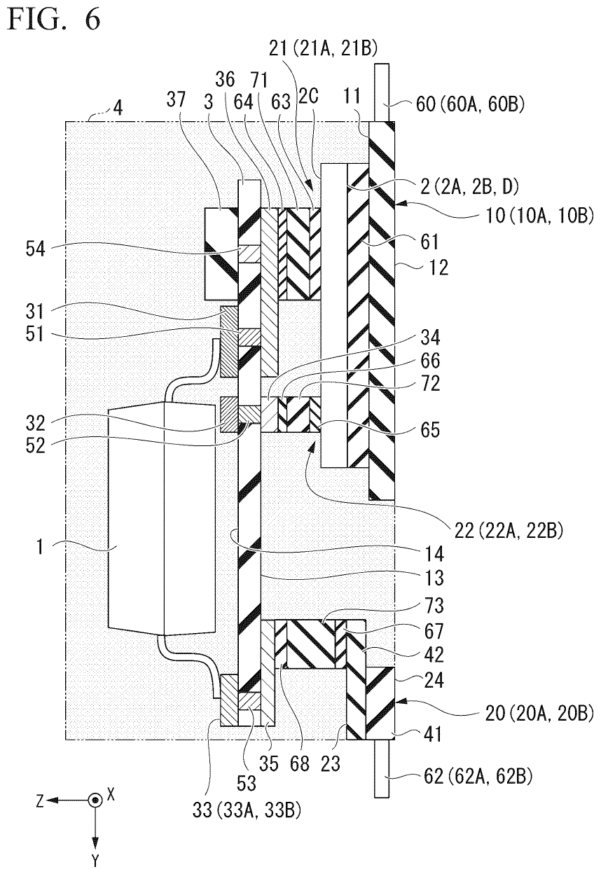

Next, a second embodiment of the semiconductor device 100 will be described with reference to FIGS. 5 and 6. In the drawings, the same components as those of the first embodiment shown in FIGS. 1 to 4 are designated by the same reference numerals, and a description thereof will be omitted.

FIG. 5 is a plan view showing a structural example of the semiconductor device 100 according to the second embodiment. FIG. 6 is a cross-sectional view taken along line II-II in FIG. 5. As shown in FIGS. 5 and 6, the semiconductor device 100 of the embodiment has a connection conductor 37. The connection conductor 37 is provided on the fourth surface 14 of the substrate 3. The connection conductor 37 has a plate shape that extends in the X direction. The connection conductor 37 faces the third portion 36A (refer to FIG. 3) of the connection wiring 36 in the Z direction with the substrate 3 interposed therebetween. The connection conductor 37 is electrically connected through a via 54. The other configurations are similar to those of the first embodiment.

In the semiconductor device 100 having the above-described configuration, a current flowing through the connection wiring 36 between the semiconductor chips 2A and 2B also flows through the via 54 to the connection conductor 37. The connection wiring 36 is made of a metal foil and thus has a relatively large electrical resistance, but the connection conductor 37 has a plate shape and thus has a small electrical resistance. Therefore, the electrical resistance of the current flowing between the semiconductor chips 2A and 2B is small.

According to at least one embodiment, in addition to obtaining the same functions and effects as the first embodiment, the electrical resistance of the current flowing between the semiconductor chips 2A and 2B can be reduced, and thus it is possible to handle a larger current.

In at least one embodiment, the configuration in which two semiconductor chips 2 are provided has been exemplified, but a configuration in which only one semiconductor chip is provided may also be used. In this case, for example, when the semiconductor chip 2B shown in FIGS. 1 and 5 is not provided, a portion of the connection wiring 36 that faces the first frame 10B, and the first surface 11 of the first frame 10B may be electrically connected by the first conductor 71 and the conductive members 63 and 64.

In at least one embodiment, the configuration has been described in which an optically isolated photocoupler is used as the transmission part 1 capable of transmitting a control current in an insulated state (insulated transmission), but the present invention is not limited to this configuration. The transmission part 1 may be a discrete device such as a transistor, may be a semiconductor circuit (for example, an integrated circuit), or may be a capacitive insulation type using a capacitor.

The semiconductor element of the semiconductor chip 2 is not limited to the field effect transistor. For example, the semiconductor chip 2 may include bipolar transistors or insulated gate bipolar transistors (IGBTs). The semiconductor chip 2 may be a semiconductor circuit.

The number of transmission parts 1 included in the semiconductor device 100 of the embodiment may be two or more. The number of semiconductor chips 2 included in the semiconductor device 100 of the embodiment may be three or more.

In the semiconductor device 100 of the embodiment, the configuration in which the transmission part 1 is provided on the fourth surface 14 side of the substrate 3 is exemplified, but the present invention is not limited to this configuration. The transmission part 1 may be provided on both the fourth surface 14 side and the third surface 13 side of the substrate 3.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
at least one semiconductor chip;
a metal plate electrically connected to the semiconductor chip at a first surface configured to face the semiconductor chip in a first direction;
a substrate disposed on a side of the semiconductor chip opposite to the plate in the first direction; and
a resin body configured to cover the semiconductor chip, the first surface of the plate, and the substrate,
wherein at least a second surface of the plate opposite to the first surface in the first direction is exposed to an outside of the resin body, and
the substrate includes:
a first conductive portion and a second conductive portion electrically connected to the semiconductor chip;
a third conductive portion to which a control current is input; and
a transmission part electrically connected to the first conductive portion, the second conductive portion, and the third conductive portion and configured to transmit the control current in an insulated state.

2. The semiconductor device of claim 1, wherein the semiconductor chip includes two first electrodes each of which is electrically connected to the first conductive portion, and
the substrate has a third surface configured to face the semiconductor chip in the first direction, the third surface being connected to the first conductive portion and having a connection wiring configured to electrically connect the two first electrodes.

3. The semiconductor device of claim 1, wherein the semiconductor chip has a first electrode electrically connected to the first conductive portion,
a second plate made of a metal is provided, the second plate being disposed at the same position as the plate in the first direction to be spaced apart from the plate in a second direction perpendicular to the first direction, the second plate having one surface exposed to an outside of the resin body, and
the substrate has a third surface configured to face the semiconductor chip in the first direction, the third surface being connected to the first conductive portion and having a connection wiring electrically connected to the first electrode and the second plate.

4. The semiconductor device of claim 2, wherein the substrate has a fourth surface opposite to the third surface in the first direction, the fourth surface having a connection conductor having a plate shape and electrically connected to the connection wiring.

5. The semiconductor device of claim 2, wherein a second plate made of a metal is provided, the second plate being electrically connected to the third conductive portion, being disposed to be spaced apart from the plate in a second direction perpendicular to the first direction, and having a fifth surface opposite to a facing surface configured to face the substrate in the first direction, the fifth surface being exposed to an outside of the resin body, and
the second plate has:
a first portion having the fifth surface and configured to extend in a third direction in which a creepage distance between the first portion and the plate is constant; and
a second portion provided on a substrate side of the first portion in the first direction, configured to protrude toward the plate further than the first portion in the second direction, and electrically connected to the third conductive portion.

6. The semiconductor device of claim 2, wherein the semiconductor chip has a second electrode electrically connected to the second conductive portion,
the substrate has, on the third surface, a fourth conductive portion connected to the second conductive portion and a fifth conductive portion connected to the third conductive portion,
a second plate made of a metal is provided, the second plate being electrically connected to the third conductive portion, being disposed to be spaced apart from the plate in a second direction perpendicular to the first direction, and having a fifth surface opposite to a facing surface configured to face the substrate in the first direction, the fifth surface being exposed to an outside of the resin body,
the semiconductor device includes:
a first conductor disposed between the connection wiring and the first electrode and configured to adjust a distance between the connection wiring and the first electrode;
a second conductor disposed between the fourth conductive portion and the second electrode and configured to adjust a distance between the fourth conductive portion and the second electrode; and
a third conductor disposed between the fifth conductive portion and the second plate and configured to adjust a distance between the fifth conductive portion and the second plate.

7. The semiconductor device of claim 1, wherein the transmission part includes an optical coupling device, and
the semiconductor chip includes a transistor.

8. The semiconductor device of claim 1, wherein the transmission part includes a photocoupler.
